(19) United States
(12) Patent Application Publication
(10) Pub. No.: US 2015/0034910 A1
(43) Pub. Date: Feb. 5, 2015

(54) ORGANIC X-RAY DETECTOR

(71) Applicant: GENERAL ELECTRIC COMPANY, Schenectady, NY (US)

(72) Inventors: Gautam Parthasarathy, Niskayuna, NY (US); Aaron Judy Couture, Schenectady, NY (US); Jie Jerry Liu, Niskayuna, NY (US); Kwang Hyup An, Rexford, NY (US)

(73) Assignee: GENERAL ELECTRIC COMPANY, Schenectady, NY (US)

(21) Appl. No.: 13/955,355

(22) Filed: Jul. 31, 2013

(51) Int. Cl. H01L 27/30; H01L 51/00; H01L 51/44

(52) U.S. Cl. CPC H01L 27/308; H01L 27/307; H01L 51/44; H01L 51/0046
USPC 257/40; 438/59

(57) ABSTRACT

An x-ray imaging system includes an organic x-ray detector having a layered structure composed of a scintillator layer disposed on a first electrode layer and an absorber layer sandwiched between the first electrode layer and a second electrode layer. The second electrode layer is disposed on a TFT array and the TFT array is disposed on a substrate. The absorber layer includes a donor material and an acceptor material, and the donor material contains a low bandgap polymer.

### BACKGROUND

A major limitation of current portable digital x-ray detectors is high cost and limited ruggedness. Digital x-ray devices based on a fragile glass substrate have limited ruggedness; specifications for maximum drop height may be only 30 cm. As a result, digital detectors have not been able to replace CR plates or film for some portable and low cost applications. The fragile substrate additionally dictates the need for a heavy, thick and stiff detector package, and trade-offs balancing detector ruggedness against detector weight and thickness are required. The critical barrier to a highly portable digital x-ray detector is the glass substrate. There remains a need for a low cost, high resolution, light-weight, rugged and flexible digital x-ray detector.

### BRIEF DESCRIPTION

In one aspect, the present invention relates to high performance digital organic x-ray detectors, and x-ray imaging systems employing the detectors. Organic x-ray detectors according to the present invention have a layered structure that includes a scintillator layer disposed on a first electrode layer, an absorber layer sandwiched between the first electrode layer and a second electrode layer disposed on a TFT array; and the TFT array disposed on a substrate. The absorber layer includes a donor material and an acceptor material, and the donor material includes a low bandgap polymer. In another aspect, the present invention relates to a process for fabricating the organic x-ray detectors.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic view of an organic x-ray detector according to the present invention, having a layered structure.

FIG. 2 is a schematic diagram of energy levels of materials for an organic x-ray detector according to the present invention

FIG. 3 depicts an x-ray imaging system according to the present invention including an organic x-ray detector according to the present invention.

### DETAILED DESCRIPTION

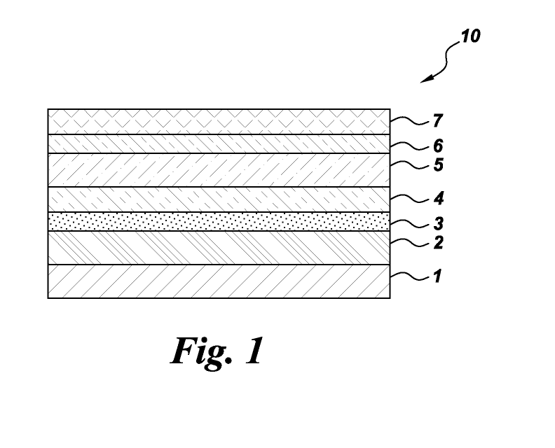

FIG. 1 shows the layered structure of an organic x-ray detector 10 according to the present invention, in which a scintillator layer 7 is disposed on a first electrode layer 6, absorber layer 5 is sandwiched between first electrode layer 6 and a second electrode 3, with second electrode layer 3 disposed on a thin film transistor (TFT) array 2 disposed on substrate 1. A charge blocking layer 4 is disposed on the second electrode layer 3. The combination of the second electrode layer 3, TFT array 2 and substrate 1 is also referred to as a TFT substrate, which may be fabricated separately from the other layers, or obtained from a commercial vendor. In some embodiments, first electrode 6 functions as the cathode and second electrode 3 as the anode and charge blocking layer 4 is an electron blocking layer. In other embodiments, first electrode 6 functions as the anode and second electrode 3 as the cathode and charge blocking layer 4 is a hole blocking layer.

Substrate 1 may be composed of a rigid or flexible material. Examples of suitable materials for the substrate include glass, which may be rigid or flexible, plastics such as polyethylene terephthalate, polybutylene phthalate, polyethylene naphthalate, polystyrene, polycarbonate, polyether sulfone, polyallylate, polyimide, polycycloolefin, norbornene resins, and fluoropolymers, metals such as stainless steel, aluminum, silver and gold, metal oxides, such as titanium oxide and zinc oxide, and semiconductors such as silicon. Combinations of materials may also be used. By using an unbreakable material instead of a fragile glass substrate for the x-ray detector, the components and materials designed to absorb bending stress or drop shock can be reduced in size and weight or eliminated, and the overall weight and thickness of the detector can be reduced. Removing costly materials which are used to protect the glass substrate decreases the overall cost of the detector. In addition, the number of patterned layers needed for the detector can be reduced by utilizing an un-patterned low cost organic photodiode.

Thin film transistor (TFT) layer 2 is a two dimensional array of passive or active pixels which store charge for read out by electronics, disposed on an active layer formed of amorphous silicon or an amorphous metal oxide, or organic semiconductors. Suitable amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ where m is <6) and InGaZnO₄. Suitable organic semiconductors include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene) and poly(p-phenylene vinylene) and derivatives thereof. Each pixel contains a patterned second electrode 3.

Organic x-ray detector 10 may include at least one charge blocking layer that forms a barrier to dark leakage current when the diode is reverse biased. The charge blocking layer may be a continuous patterned or unpatterned conductive layer; in some embodiments, completely covering second electrode 3. A range of materials satisfying the HOMO/LUMO/mobility requirements may be used for when charge blocking layer 4 is an electron blocking layer, including, but not limited to, aromatic tertiary amines and polymeric aromatic tertiary amines. Examples of suitable materials include poly-TPD (poly(4-butylphenyl-diphenyl-amine), poly(N,N′-bis(4-butylphenyl)-N,N′-bis(phenyl)benzidine, 4,4′,N,N′-diphenylcarbazole, 1,3,5-tris(3-methyldiphenyl-amino)benzene, N,N′-bis(1-naphtalenyl)-N—N′-bis(phenylbenzidine), N,N′-Bis-(3-methylphenyl)-N,N′-bis(phenyl)benzidine, N,N′-bis(2-naphtalenyl)-N—N′-bis-(phenylbenzidine), 4,4′,4″-tris(N,N-phenyl-3-methylphenylamino)triphenylamine, poly[9,9-dioctylfluorenyl-2,7-dyil)-co-(N,N′ bis-(4-butylphenyl-1,1′-biphenylene-4,4-diamine)], poly(N,N′-bis(4-butylphenyl)-N,N′-bis(phenyl)benzidine, poly[(9,9-dihexylfluorenyl-2,7-diyl)-co-(N,N′ bis{p-butylphenyl}-1,4-diamino-phenylene)], NiO, MoO3, tri-p-tolylamine, 4,4′,4″-tris[phenyl(m-tolyl)amino]triphenylamine, 4,4′,4″-tris[2-naphthyl(phenyl)amino]triphenylamine, 1,3,5-tris[(3-methylphenyl)phenylamino]benzene, 1,3,5-tris(2-(9-ethylcabazyl-3)ethylene)benzene, 1,3,5-tris(diphenylamino)benzene, tris[4-(diethylamino)phenyl]amine, tris(4-carbazoyl-9-ylphenyl)amine, titanyl phthalocyanine, tin(IV) 2,3-naphthalocyanine dichloride, N,N,N′,N′-tetraphenyl-naphthalene-2,6-diamine, tetra-N-phenylbenzidine, N,N,N′,N′-tetrakis(2-naphthyl) benzidine, N,N,N′,N′-tetrakis(3-methylphenyl)-3,3′-dimethylbenzidine, N,N,N′,N′-tetrakis(4-methoxyphenyl)benzidine, poly(2-vinylnaphthalene), poly(2-vinylcarbazole), poly(N-ethyl-2-vinylcarbazole), poly(copper phthalocyanine), poly[bis(4-phenyl)(2,4,6-trimethylphenyl)amine], dipyrazino[2,3-f:2′,3′-h]quinoxaline-2,3,6,7,10,11-hexacarbonitrile 99%, N,N′-diphenyl-N,N′-di-p-tolylbenzene-1,4-diamine, 4-(diphenylamino)benzaldehyde diphenylhydrazone, N,N′-di(2-naphthyl-N,N′-diphenyl)-1,1′-biphenyl-4,4′-diamine, 9,9-dimethyl-N,N′-di(1-naphthyl)-N,N′-diphenyl-9H-fluorene-2,7-diamine, 2,2′-dimethyl-N,N′-di-[(1-naphthyl)-N,N′-diphenyl]-1,1′-biphenyl-4,4′-diamine, 4-(dibenzylamino)benzaldehyde-N,N-diphenylhydrazone, 4,4′-Cyclohexylidenebis[N,N-bis(4-methylphenyl)benzenamine], N,N′-Bis(phenanthren-9-yl)-N,N′-bis(phenyl)-benzidine, N,N′-Bis(3-methylphenyl)-N,N′-diphenylbenzidine, 4,4′-Bis(3-ethyl-N-carbazolyl)-1,1′-biphenyl, 1,4-Bis(diphenylamino)benzene, 4,4′-Bis(N-carbazolyl)-1,1′-biphenyl, 4,4′-Bis(N-carbazolyl)-1,1′-biphenyl, and 1,3-Bis(N-carbazolyl)benzene. In some embodiments, a donor material may function as the EBL material, and a charge blocking layer may be absent.

Absorber layer 5 is composed of at least a donor material and an acceptor material; the donor material contains at least one low bandgap polymer. It is a continuous, unpatterned bulk hetero-junction organic photodiode layer that absorbs light, separates charge and transports holes and electrons to the contact layers. In some embodiments, the absorber may be patterned. HOMO/LUMO levels of the donor and acceptor materials are compatible with that of charge blocking layer 3 when present and of the first and second electrodes in order to allow efficient charge extraction without creating an energetic barrier. Absorber layer 5 may be composed of a blend of a donor material and an acceptor material; more than one donor or acceptor may be included in the blend. In some embodiments, the donor and acceptor may be incorporated in the same molecule Suitable donor materials are low bandgap polymer having LUMO ranging from about 1.9 eV to about 4.9 eV, particularly from 2.5 eV to 4.5 eV, more particularly from 3.0 eV to 4.5 eV; and HOMO ranging from about 2.9 eV to about 7 eV, particularly from 4.0 eV to 6 eV, more particularly from 4.5 eV to 6 eV. The low band gap polymers are conjugated polymers and copolymers composed of units derived from substituted or unsubstituted monoheterocyclic and polyheterocyclic monomers such as thiophene, fluorene, phenylenvinylene, carbazole, pyrrolopyrrole, and fused heteropolycyclic monomers containing the thiophene ring, including, but not limited to, thienothiophene, benzodithiophene, benzothiadiazole, pyrrolothiophene monomers, and substituted analogs thereof. In particular embodiments, the low band gap polymers comprise units derived from substituted or unsubstituted thienothiophene, benzodithiophene, benzothiadiazole, carbazole, isothianaphthene, pyrrole, benzo-bis(thiadiazole), thienopyrazine, fluorene, thiadiazolequinoxaline, or combinations thereof. In the context of the low band gap polymers described herein, the term “units derived from” means that the units are each a residue comprising the monoheterocyclic and polyheterocyclic group, without regard to the substituents present before or during the polymerization; for example, “the low band gap polymers comprise units derived from thienothiophene” means that the low band gap polymers comprise divalent thienothiophenyl groups. Examples of suitable materials for use as low bandgap polymers in the organic x-ray detectors according to the present invention include copolymers derived from substituted or unsubstituted thienothiophene, benzodithiophene, benzothiadiazole or carbazole monomers, and combinations thereof, such as poly[[4,8-bis[(2-ethyl hexyl)oxy]benzo[1,2-b:4,5-b′]dithiophene-2,6-diyl][3-fluoro-2-[(2-ethylhexyl)carbonyl]thieno[3,4-b]thiophenediyl (PTB7), 2,1,3-benzothiadiazole-4,7-diyl[4,4-bis(2-ethylhexyl)-4H-cyclopenta[2,1-b:3,4-b′]dithiophene-2,6-diyl (PCPDTBT), poly[[9-(1-octylnonyl)-9H-carbazole-2,7-diyl]-2,5-thiophenediyl-2,1,3-benzothiadiazole-4,7-diyl-2,5-thiophenediyl] (PCDTBT), poly[(4,40-bis(2-ethylhexyl)dithieno[3,2-b:20,30-d]silole)-2,6-diyl-alt-(2,1,3-benzothiadiazole)-4,7-diyl] (PSBTBT), poly((4,8-bis(octyloxy)benzo(1,2-b:4,5-b′)dithiophene-2,6-diyl)(2-((dodecyloxy)carbonyl)thieno(3,4-b)thiophenediyl)) (PTB1), poly((4,8-bis(octyloxy)benzo(1,2-b:4,5-b′)dithiophene-2,6-diyl)(2-((ethylhexyloxy)carbonyl)thieno(3,4-b)thiophenediyl)) (PTB2), poly((4,8-bis(octyl)benzo(1,2-b:4,5-b′)dithiophene-2,6-diyl) (2-((ethylhexyloxy)carbonyl) thieno(3,4-b)thiophenediyl)) (PTB3), poly((4,8-bis-(ethylhexyloxybenzo(1,2-b:4,5-b′)dithiophene-2,6-diyl)(2-((octyloxy)carbonyl)-3-fluoro)thieno(3,4-b)thiophenediyl)) (PTB4), poly((4,8-bis(ethylhexyloxybenzo(1,2-b:4,5-b′)dithiophene-2,6-diyl)(2-((octyloxy)carbonyl) thieno(3,4-b)thiophenediyl)) (PTB5), poly((4,8-bis(octyloxy)benzo(1,2-b:4,5-b′)dithiophene-2,6-diyl)(2-((butyloctyloxy)carbonyl) thieno(3,4-b)thiophenediyl)) (PTB6), poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5-b′]dithiophene-2,6-diyl]] (PBDTTPD), poly[1-(6-{4,8-bis[(2-ethylhexyl)oxy]-6-methylbenzo[1,2-b:4,5-b′]dithiophene-2-yl}-3-fluoro-4-methylthieno[3,4-b]thiophen-2-yl)-1-octanone] (PBDTTT-CF), and poly[2,1,3-benzothiadiazole-4,7-diyl-2,5-thiophenediyl (9,9-dioctyl-9H-9-silafluorene-2,7-diyl)-2,5-thiophenediyl] (PSiF-DBT). Other suitable materials are poly[5,7-bis(4-decanyl-2-thienyl) thieno[3,4-b]diathiazole-thiophene-2,5] (PDDTT), poly[2,3-bis(4-(2-ethylhexyloxy)phenyl)-5,7-di(thiophen-2-yl)thieno[3,4-b]pyrazine] (PDTTP), and polythieno[3,4-b]thiophene (PTT). In particular embodiments, suitable materials are copolymers derived from substituted or unsubstituted benzodithiophene monomers, such as the PTB1-7 series and PCPDTBT; or benzothiadiazole monomers, such as PCDTBT and PCPDTBT. In particular embodiments, the donor material is a polymer with a low degree of crystallinity or is an amorphous polymer. Degree of crystallinity may be increased by substituting aromatic rings of the main polymer chain. Long chain alkyl groups containing six or more carbons or bulky polyhedral oligosilsesquioxane (POSS) may result in a polymer material with a lower degree of crystallinity than a polymer having no substituents on the aromatic ring, or having short chain substituents such as methyl groups. Degree of crystallinity may also be influenced by processing conditions and means, including, but not limited to, the solvents used to process the material and thermal annealing conditions. Degree of crystallinity is readily determined using analytical techniques such as calorimetry, differential scanning calorimetry, x-ray diffraction, infrared spectroscopy and polarized light microscopy.

Suitable materials for the acceptor include fullerene derivatives such as [6,6]-phenyl-C₆₁-butyric acid methyl ester (PCBM), PCBM analogs such as PC₇₀BM, PC₇₁BM, PC₈₀BM, bis-adducts thereof, such as bis-PC₇₁BM, indene mono-adducts thereof, such as indene-C₆₀ monoadduct (ICMA) and indene bis-adducts thereof, such as indene-C₆₀ bisadduct (ICBA). Fluorene copolymers such as poly[(9,9-dioctylfluorenyl-2,7-diyl)-alt-(4,7-bis(3-hexylthiophene-5-yl)-2,1,3-benzothiadiazole)-2′,2″-diyl] (F8TBT) may also be used, alone or with a fullerene derivative.

An optional charge blocking layer (HBL) (not shown) may be disposed between the absorber layer 5 and the first electrode 6. Where the first electrode is a cathode, the charge blocking layer is a hole blocking layer. Suitable materials for the hole blocking layer include phenanthroline compounds, for example, 2,9-dimethyl-4,7-diphenyl-1,10-phenanthroline (BCP), 4-biphenyloxolate aluminum(III) bis(2-methyl-8-quinolinato)-4-phenylphenolate (BAIq), 2,4-diphenyl-6-(49-triphenylsilanyl-biphenyl-4-yl)-1,3,5-triazine (DTBT), C60, (4,4′-N,N′-dicarbazole)biphenyl (CBP), as well as a range of metal oxides, such as TiO₂, ZnO, Ta₂O₅, and ZrO₂. Where the first electrode is an anode, the charge blocking layer is an electron blocking layer.

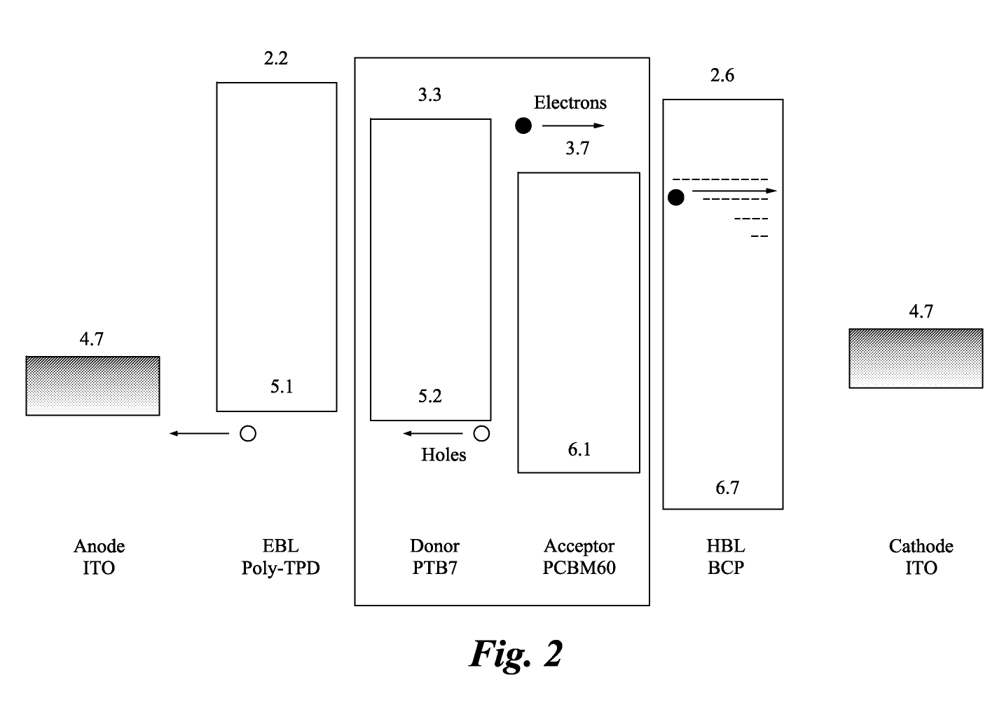

FIG. 2 is an energy level diagram for one embodiment of an organic x-ray detector comprising an anode electrode, an electron-blocking layer (EBL) disposed between an absorber layer and the anode, and a cathode electrode. For efficient extraction with high quantum efficiency and low dark current, the following orientation of energy levels may be used. To reduce dark current due to electron leakage, the LUMO of the EBL should be less than the LUMO of the acceptor, that is, closer to the vacuum level than the LUMO of the acceptor. To improve extraction of holes and hence the external quantum efficiency (EQE) of the device, the HOMO of the EBL should be less than the HOMO of the donor, that is, closer to the vacuum level than the HOMO of the donor. For efficient extraction of electrons, the LUMO of the HBL should be greater than the LUMO of the acceptor, that is, further from the vacuum level than the acceptor. Mid-gap defect states can offer a pathway for extraction of electrons to the cathode. To prevent dark current due to holes, the HOMO of the HBL should be greater than the HOMO of the donor.

First electrode 6 is a semi-transparent conductive layer with compatible energy levels to allow extraction of charges without a barrier to extraction; transparent at the wavelength of emissions from scintillator 7, particularly high in the transmission to visible light and low in resistance value. In one embodiment, the first electrode functions as the cathode and the second electrode as the anode and the charge blocking layer 4 is the electron blocking layer. In another embodiment, the first electrode functions as the anode and the second electrode as the cathode and the charge blocking layer 4 is the hole blocking layer. Suitable anode materials include, but are not limited to, metals such as Al, Ag, Au, and Pt, metal oxides such as ITO, IZO, and ZO, and organic conductors such as p-doped conjugated polymers like PEDOT. Suitable cathode materials for include transparent conductive oxides (TCO) and thin films of metals such as gold and silver. Examples of suitable TCO include ITO, IZO, AZO, FTO, SnO₂, TiO₂, ZnO, indium zinc oxides (In—Zn—O series), indium gallium oxides, gallium zinc oxides, indium silicon zinc oxides, and IGZO. In many embodiments, ITO is used because of its low resistance and transparency. First electrode 6 may be formed as one layer over an entire pixel portion or may be divided forming a lateral offset and/or vertical offset between the electrode and the data readout lines to reduce electronic noise that may result from capacitive coupling between the electrode of the photosensor control and a data readout line of the TFT array as described in copending U.S. Ser. No. 13/728,052, filed on Dec. 27, 2012, incorporated herein by reference.

Scintillator layer 7 is composed of a phosphor material that is capable of converting x-rays to visible light. The wavelength region of light emitted by scintillator 7 ranges from about 360 nm to about 830 nm. Suitable materials for the layer include, but are not limited to, cesium iodide (Csl), Csl (TI) (cesium iodide to which thallium has been added) and terbium-activated gadolinium oxysulfide (GOS). Such materials are commercially available in the form of a sheet or screen. Scintillator layer 7 may include an adhesive layer (not shown) disposed on first electrode 6 for attaching a scintillator sheet.

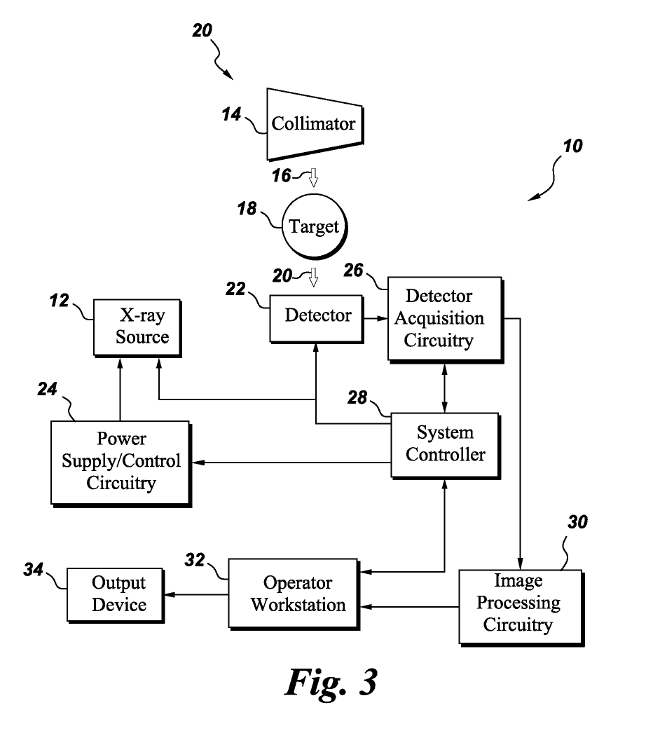

FIG. 3 shows an embodiment of an x-ray imaging system 20 according to the present invention, which may be designed to acquire and process X-ray image data. The system 10 includes an X-ray source 12, a collimator 14, and a detector 22. The X-ray source 12 may be positioned adjacent to the collimator 14. The X-ray source 12 may be a low-energy source to be employed in low energy imaging techniques, such as fluoroscopic techniques. The collimator 14 may permit a stream of X-ray radiation 16 emitted by the X-ray source 12 to radiate towards a target 18, such as a human patient. A portion of the X-ray radiation is attenuated by the target 18 and at least some attenuated radiation 20 impacts the detector 22, such as a fluoroscopic detector.

Detector 22 may be based on scintillation, i.e., optical conversion, direct conversion, or on other techniques used in the generation of electrical signals based on incident radiation. For example, a scintillator-based detector converts X-ray photons incident on its surface to optical photons. These optical photons may then be converted to electrical signals by employing photosensor(s), e.g., photodiode(s). Conversely, a direct conversion detector directly generates electrical charges in response to incident X-ray photons. The electrical charges may be stored and read out from storage capacitors. As described in detail below, these electrical signals, regardless of the conversion technique employed, are acquired and processed to construct an image of the features (e.g., anatomy) within the target 18.

X-ray source 12 is controlled by power supply/control circuitry 24 which furnishes both power and control signals for examination sequences. Moreover, detector 22 may be coupled to detector acquisition circuitry 26, which may be configured to receive electrical readout signals generated in the detector 22. Detector acquisition circuitry 26 may also execute various signal processing and filtration functions, such as, for initial adjustment of dynamic ranges, interleaving of digital, and so forth.

In the depicted exemplary embodiment, one or both of the power supply/control circuitry 24 and detector acquisition circuitry 26 may be responsive to signals from controller 28. System controller 28 may include signal processing circuitry, typically based upon a general purpose or application specific digital computer programmed to process signals according to one or more parameters. The system controller 28 may also include memory circuitry for storing programs and routines executed by the computer, as well as configuration parameters and image data, interface circuits, and so forth.

The system 10 may include image processing circuitry 30 configured to receive acquired projection data from the detector acquisition circuitry 26. The image processing circuitry 30 may be configured to process the acquired data to generate one or more images based on X-ray attenuation.

An operator workstation 32 may be communicatively coupled to the system controller 28 and/or the image processing circuitry 30 to allow an operator to initiate and configure X-ray imaging of a target and to view images generated from X-rays that impinge the detector 22. For example, the system controller 28 is in communication with the operator workstation 32 so that an operator, via one or more input devices associated with the operator workstation 32, may provide instructions or commands to the system controller 28.

Similarly, the image processing circuitry 30 may be in communication with the operator workstation 32 such that the operator workstation 32 may receive and display the output of the image processing circuitry 30 on an output device 34, such as a display or printer. The output device 34 may include standard or special purpose computer monitors and associated processing circuitry. In general, displays, printers, operator workstations, and similar devices supplied within the system may be local to the data acquisition components or may be remote from these components, such as elsewhere within an institution or hospital or in an entirely different location. Output devices and operator workstations that are remote from the data acquisition components may be operatively coupled to the image acquisition system via one or more configurable networks, such as the internet, virtual private networks, and so forth. As will be appreciated by one of ordinary skill in the art, though the system controller 28, image processing circuitry 30, and operator workstation 32 are shown distinct from one another in FIG. 3, these components may actually be embodied in a single processor-based computing system. Alternatively, some or all of these components may be present in distinct processor-based computing systems configured to communicate with one another. For example, the image processing circuitry 30 may be a component of a distinct reconstruction and viewing workstation.

An x-ray detector according to the present invention may be used in conformal imaging, with the detector in intimate contact with the imaging surface. For parts with internal structure, the detector may be rolled or shaped to contact the part being imaged. Applications for flexible, light-weight, highly rugged detectors according to present invention include security and medical imaging, and industrial and military imaging for pipeline, fuselage, airframe and other tight access areas.

Processes for fabricating an organic x-ray detector include disposing an absorber layer on a patterned electrode layer of a TFT substrate, disposing an absorber layer on the patterned electrode layer, and disposing an electrode layer on the absorber layer, and disposing a scintillator layer on the electrode layer opposite to the absorber layer. The absorber layer contains an acceptor material comprising a fullerene derivative, a donor material comprising a low bandgap polymer, and a solvent. Suitable solvents solubilize both donor and acceptor materials over a range of concentrations, and yield desired film microstructures and thicknesses. Examples include, but are not limited to, 1,2-dichlorobenzene, chlorobenzene, xylenes, methyl-naphthalene, and combinations thereof. The absorber layer may be crosslinked in order to reduce solubility of the donor material; crosslinking may be initiated thermally or by exposure to radiation.

In some embodiments, a charge blocking layer is disposed on the first electrode prior to the step of disposing the absorber layer. In some embodiments, crosslinkable materials may be used for the charge blocking layer, and are crosslinked before the absorber layer is coated thereon thermally or by exposure to radiation in order to prevent wash-out. The crosslinking process may be designed to prevent substrate deformation or device damage when a polymer material is used as a substrate, and curing temperature and time are typically dependent on the particular materials used. In one example, a layer composed of a polyamine in a device containing a plastic substrate may be cured at 180° C. for 1-hours. Alternatively, the absorber layer may be coated from an orthogonal solvent, that is, one that does not dissolve the material of the electron blocking layer.

After the curing cycle, the absorber layer may be coated on the charge blocking layer from a coating solution without damage to the charge blocking layer. Following solution coating of the organic photo detector, a second electrode is deposited onto its surface by means such as thermal evaporation, sputtering and direct printing etc. Where a hole blocking layer is disposed on the absorber layer prior to the step of disposing the second electrode layer, the electrode is disposed directly on the hole blocking layer, by sputtering or any other suitable method, including wet coating processes. The scintillator layer is then disposed on the electrode. In many embodiments, the scintillator is present in the form of a screen or film, where the scintillator material is dispersed in a polymer film, and may be attached to the cathode via a pressure sensitive adhesive. Product electronics may then be bonded to the detector, and assembled into a product enclosure.

### EXAMPLES

Bulk heterojunction organic photodiodes were fabricated using poly(3-hexylthiophene) as the electron donor and [6,6]-phenyl-C61 butyric acid methyl ester as the electron acceptor. Additionally, PTB7 {Poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]]} and PCDTBT {poly(2,7-carbazole) derivative, poly[N-900-hepta-decanyl-2,7-carbazole-alt-5,5-(40,70-di-2-thienyl-20,10,30-benzothiadiazole)]} were used as donors. PCDTBT and PTB7 were purchased from 1-Material, Quebec, Canada. P3HT electron donor (regioregular head to tail coupled P3HT) and PCBM are available from Aldrich. The purchased materials were received and then stored in a nitrogen box until they were processed into thin films in a nitrogen filled glovebox.

Devices were fabricated by first cleaning 1″ indium tin oxide (ITO) coated glass (120 nm ITO from Applied Films) by sequential ultrasonication in acetone and isopropanol. The ITO was patterned using photolithography into a ½ inch stripe to define the anode of the device. After removal from the isopropanol, the glass substrates were blown dry with filtered house nitrogen and were further cleaned by exposure to UV ozone for 15 minutes. After surface preparation, substrates were transferred into the nitrogen glovebox (<1.0 ppm O2 and H2O) for deposition of the absorber blend. In some cases, the substrates were coated with a thin film of polyamine. The polyamine was dissolved in toluene and double-filtered through 0.45 um-1.0 um PVDF or glass microfiber filter (Whatman) before dispensing the material onto the glass substrates using a polyethylene pipette. The resulting film was rendered insoluble by exposure to uv or by a thermal bake. A Chemat KW-4A spinner was used to spin coat all materials. The active absorber blend was prepared in the nitrogen glovebox by dissolving one of the donors above and PCBM at 20-80 mg/mL at a 1:1 weight ratio into 1,2-dichlorobenzene, chlorobenzene, xylenes and/or methyl-naphthalene.

The solution was heated on a hotplate for 60 min and then filtered through a 0.45 um-1.0 um PVDF or glass microfiber filter. A polyethylene pipette was used to dispense the solution in a clockwise outward spiral manner over the entire surface of the substrates then transferred the substrates to a thermal evaporator for cathode deposition. Film thickness reproducibility is generally quite good when processing in a nitrogen glovebox. A bilayer cathode consisting of 3.5 nm of Ca was deposited, followed by 100 nm of Al through a shadow mask with openings perpendicular to the ½″ ITO stripe resulting in OPDs with an active area of 0.2 cm². A series of other cathode materials was examined, including thermally evaporated LiF, CsF, NaF, KF, Ag, and sputtered ITO. Finally. the 1″ OPDs and OPD-based light imagers were encapsulated using a commercially available single part ultraviolet (UV) light cured adhesive (ELC 2500 Clear from Electro-Lite Corporation, Bethel, Conn.) to adhere a cleaned microscope cover slip to the glass substrate. The encapsulated devices were then removed from the nitrogen glovebox and laminated to commercially available GOS scintillator screens (Mitsubishi) to form x-ray detectors. OPD-based light imagers consisted of 5 cm glass substrates coated with an array of a-Si or IGZO thin film transistors, on which the OPD was fabricated.

The OPDs were characterized by current-density vs. voltage (J-V) curves and EQE at a fixed voltage. J-V characterization was performed using a Keithley 6480 automated with a C++ script and EQE measurements were performed using a calibrated Oriel EQE measurement system. (Newport/Oriel IQE-200 Integrated Measurement System). The light imagers were characterized in a functional tester. Image lag was assessed qualitatively based on the amount of image shading, ghosting and related image distortion effects.

Properties of devices fabricated with P3HT or an LBG polymer as a donor are shown in Table 1. When combined with poly-amine, materials having a HOMO>5.2, such as PTB7, and materials having a HOMO of 5.2, such as PCDTBT, did not show any significant reduction in the external quantum efficiency and had no significant reduction in EQE or slightly reduced EQEs. Materials having HOMO less than 5.2, such as P3HT, had significantly reduced EQEs, a more severe voltage dependence to the EQE and poor lag. It is also noted that both PTB7 and PCDTBT exhibit a lower degree of crystallinity or amorphous than P3HT, which is known as a crystalline polymer.

HOMO-LUMO energy levels were determined through cyclic voltammetry using a CH Instruments CHI660 EC Workstation. The polymer materials were dissolved in the electrolyte at concentrations of 1 mg/ml. Thin films of the polymer materials were spun onto a 2 mm diameter carbon disk working electrode (CH Instruments CHI102). The electrolyte was 0.1 Molar Tetrabutylammonium tetrafluoroborate (TBATFB) in anhydrous dimethylformamide (DMF, from Aldrich). The TBATFB was dried overnight at 90 C under vacuum; the DMF was used as received. The electrolyte was stored in a rinsed bottle with a Teflon-lined septum cap. The cap was wrapped in parafilm and the bottle was stored in a closed jar containing Drierite (CaSO4) desiccant to minimize water contamination. All transfers from the bottle were done with a syringe to remove the electrolyte. A second needle connected to a dry nitrogen line was also in the septum to replace the removed volume with nitrogen.

A three electrode electrochemical cell was employed with a coiled Pt wire auxiliary electrode and a 0.01M Ag/AgNO3 non-aqueous reference electrode CH Instruments CHI. and was degassed by 5 minutes of nitrogen bubbling. 1V/s scan rate. The reference potential was calibrated with a 1.3 mM ferrocene standard whose redox potential was defined as 4.8 eV with respect to vacuum. From this, zero potential on the CV plots is 4.7 eV with respect to vacuum. HOMO-LUMO energy levels were determined from the onset of the polymer's oxidation or reduction steady state voltammograms, typically scans 5-8. The HOMO-LUMO energy levels were defined as the intersection of the linear extrapolation of the onset slope of the respective peak and the baseline.

TABLE 1

| | Leakage | | |
|---|---|---|---|
| Structure | pA/cm² | EQE (%) | Lag |
| P3HT:PCBM | 10⁵ | 65 | Good |
| Poly-TPD/P3HT:PCBM | 10³-10⁵ | 2 | Poor |
| PCDTBT:PCBM | 10³ | 65 | Good |
| PTB7:PCBM | 10³ | 65 | Good |
| Poly-TPD/PCDTBT:PCBM | 10 | 45 | Good |
| Poly-TPD/PTB7:PCBM | 10 | 65 | Good |

Approximating language, as used herein throughout the specification and claims, may be applied to modify any quantitative representation that could permissibly vary without resulting in a change in the basic function to which it is related. Accordingly, a value modified by a term or terms, such as “about” is not to be limited to the precise value specified. In some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An organic x-ray detector having a layered structure comprising a scintillator layer disposed on a first electrode layer;
an absorber layer sandwiched between the first electrode layer and second electrode layer;
the second electrode layer disposed on a TFT array; and
the TFT array disposed on a substrate;
wherein the absorber layer comprises an acceptor material and a donor material comprising a low bandgap polymer.

2. An organic x-ray detector according to claim 1, additionally comprising at least one charge blocking layer disposed between the absorber layer and the first or second electrode layer.

3. An organic x-ray detector according to claim 1, wherein the TFT array has an active layer formed from amorphous silicon.

4. An organic x-ray detector according to claim 1, wherein the TFT array has an active layer formed from IGZO.

5. An organic x-ray detector according to claim 1, wherein the low bandgap polymer comprises units derived from substituted or unsubstituted thienothiophene, benzodithiophene, benzothiadiazole, pyrrolothiophene, carbazole, or a combination thereof.

6. An organic x-ray detector according to claim 1, wherein the low bandgap polymer comprises units derived from substituted or unsubstituted benzodithiophene or benzodithiazole.

7. An organic x-ray detector according to claim 1, wherein the low bandgap polymer has a HOMO greater than or equal to 5.2 eV.

8. An organic x-ray detector according to claim 1, wherein the low bandgap polymer has a HOMO greater than 5.2 eV.

9. An organic x-ray detector according to claim 1, wherein the acceptor material is a fullerene derivative.

10. An organic x-ray detector according to claim 1, wherein the first electrode layer is disposed directly on the absorber layer.

11. A process for fabricating an organic x-ray detector, the process comprising disposing an absorber layer on a patterned second electrode layer of a TFT substrate disposed on a substrate;
disposing a first electrode layer on the absorber layer; and
disposing a scintillator layer on the first electrode layer;
wherein the absorber layer comprises a fullerene derivative, a low bandgap polymer, and a solvent.

12. A process according to claim 11, wherein a charge blocking layer is disposed on the second electrode prior to the step of disposing the absorber layer.

13. A process according to claim 11, wherein a charge blocking layer is disposed on the absorber layer prior to the step of disposing the first electrode layer.

14. A process according to claim 11, wherein the first electrode layer is disposed directly on the absorber layer

15. An x-ray imaging system comprising an organic x-ray detector having a layered structure comprising
a scintillator layer disposed on a first electrode layer;
an absorber layer sandwiched between the first electrode layer and second electrode layer;
the second electrode layer disposed on a TFT array; and
the TFT array disposed on a substrate;
wherein the absorber layer comprises an acceptor material and a donor material comprising a low bandgap polymer.

16. An x-ray imaging system according to claim 15, additionally comprising a charge blocking layer disposed between the absorber layer and the first electrode layer.

17. An x-ray imaging system according to claim 15, wherein the TFT array has an active layer formed from amorphous silicon.

18. An x-ray imaging system according to claim 15, wherein the TFT array has an active layer formed from IGZO.

19. An x-ray imaging system according to claim 15, wherein the low bandgap polymer comprises units derived from substituted or unsubstituted thienothiophene, benzodithiophene, benzothiadiazole, pyrrolothiophene, carbazole, or a combination thereof.

20. An organic x-ray detector according to claim 15, wherein the low bandgap polymer comprises units derived from substituted or unsubstituted benzothiadiazole or benzodithiophene.

21. An x-ray imaging system according to claim 15, wherein the low bandgap polymer has a HOMO greater than or equal to 5.2 eV.

22. An x-ray imaging system according to claim 15, wherein the low bandgap polymer has a HOMO greater than 5.2 eV.

23. An x-ray imaging system according to claim 15, wherein the acceptor material is a fullerene derivative.

24. An x-ray imaging system according to claim 15, wherein the first electrode layer is disposed directly on the absorber layer.
